(19) United States
(12) Patent Application Publication
(10) Pub. No.: US 2026/0106119 A1
(43) Pub. Date: Apr. 16, 2026

(54) PLASMA PROCESSING DEVICE AND METHOD FOR REMOVING OXIDE FILM USING THE SAME

(71) Applicant: ELUtechnology Co., Ltd., Hwaseong-si (KR)

(72) Inventors: Myung Sok KO, Yongin-si (KR); Young Ho KIM, Hwaseong-si (KR); Young Bae LEE, Suwon-si (KR)

(73) Assignee: ELUtechnology Co., Ltd., Hwaseong-si (KR)

(21) Appl. No.: 18/939,436

(22) Filed: Nov. 6, 2024

(30) Foreign Application Priority Data
Oct. 15, 2024 (KR) 10-2024-0139924

(51) Int. Cl. H01J 37/32

(52) U.S. Cl. CPC H01J 37/32568; H01J 37/32183; H01J 37/3244; H01J 2237/002; H01J 2237/335

(57) ABSTRACT

Disclosed are a plasma processing device and a method for removing an oxide film using the same. The plasma processing device includes a holder that supports an object to be processed, an electrode module that is disposed over the holder and that includes an electrode, and a power supply module that supplies power to the electrode of the electrode module, and when viewed in a plan view, the electrode has a surface shape having a size overlapping the entire area of the object disposed on the holder.

### CROSS-REFERENCE TO RELATED APPLICATIONS

A claim for priority under 35 U.S.C. § 119 is made to Korean Patent Application No. 10-2024-0139924 filed on Oct. 15, 2024 in the Korean Intellectual Property Office, the entire contents of which are hereby incorporated by reference.

### BACKGROUND

Embodiments of the present disclosure described herein relate to a plasma processing device, and more particularly, relate to a plasma processing device for effectively removing an oxide film and an organic contaminant formed on a bump or pad of an object to be processed and a method for removing an oxide film using the same.

A semiconductor chip may be manufactured through a front end process called a wafer process and a back end process (e.g., a packaging process) of bonding a wafer-level chip manufactured through the front end process with a substrate (e.g., a circuit board).

To attach the wafer chip having bumps formed thereon to pads of the substrate (e.g., pads connected to a lead frame), a process of melting the bumps at high temperature is required. By attaching the molten bumps to the pads, the wafer chip and the substrate may be electrically connected with each other to form a circuit.

The bumps and the pads may have oxide films naturally formed on the surfaces thereof due to the characteristics of materials and may be exposed to various organic contaminants in the atmosphere in production and distribution processes. The oxide films and the organic contaminants may make soldering (fusion) between the bumps and the pads difficult, or may cause defects such as cold solder joints and may reduce the reliability of a product.

Therefore, in the related art, a chemical called flux is used to remove the oxide films formed on the bumps and the pads. However, in a field where the line width between circuits is wide or signal variability is low, the use of the flux is not restricted, but in a case of a semiconductor chip that configures ultra-high integration line widths or processes high-variability signals, the flux may distort the signals or increase resistance to degrade the performance of the chip.

In addition, a cleaning process and a post process according to the use of the flux environmentally emit a lot of secondary pollutants and cost a lot of money for processing, which goes against to the trend of being environmentally friendly.

Meanwhile, as a technology to replace the aforementioned flux, a technology for removing an oxide film using atmospheric plasma is attracting attention. However, an atmospheric plasma device in the related art has a limitation in processing area due to linear irradiation, resulting in low productivity and causes re-oxidation and contamination problems in repeated processing processes.

### SUMMARY

Embodiments of the present disclosure provide a plasma processing device for effectively removing an oxide film and an organic contaminant formed on a bump or pad of an object to be processed and a method for removing an oxide film using the same.

The problems to be solved by the present disclosure are not limited to the aforementioned problems, and any other problems not mentioned herein will be clearly understood from the following description by those skilled in the art to which the present disclosure pertains.

According to an embodiment, a plasma processing device includes a holder that supports an object to be processed, an electrode module that is disposed over the holder and that includes an electrode, and a power supply module that supplies power to the electrode of the electrode module, and when viewed in a plan view, the electrode has a surface shape having a size overlapping the entire area of the object disposed on the holder.

When viewed in the plan view, a periphery of the electrode may surround the object disposed on the holder.

The plasma processing device may further include a gas supply module that is disposed on a first side of the electrode module and that supplies a processing gas.

The gas supply module may include a gas inlet disposed in a side surface of the electrode module and a plurality of distribution holes that supply the processing gas from the gas inlet in one direction.

The plurality of distribution holes may be more densely disposed as a distance from the gas inlet increases.

The plasma processing device may further include a cooling module disposed on the electrode of the electrode module.

The cooling module may include a cooling water supply pipe, a cooling water inlet channel connected to a first side of the cooling water supply pipe, and a cooling water outlet channel connected to a second side of the cooling water supply pipe.

The cooling water supply pipe may include a plurality of first sub-supply pipes and a plurality of second sub-supply pipes that extend in different directions and that are connected with each other, and the first sub-supply pipes adjacent to each other may be disposed with a smaller gap therebetween as a distance from the cooling water inlet channel increases.

The power supply module may include a matcher, and the matcher may be integrated with a plasma reactor.

According to an embodiment, a method for removing an oxide film using the plasma processing device includes a step of placing the object to be processed on the holder, a step of generating plasma by supplying the power to the electrode through the power supply module, and a step of removing an oxide film of the object by supplying the processing gas to the holder through the gas supply module.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic diagram of a plasma processing device according to an embodiment;

FIG. 2 is a plan view of an electrode and an object to be processed in FIG. 1;

FIG. 3 is a schematic diagram of the plasma processing device including a gas supply module according to an embodiment;

FIG. 4 is an enlarged view of area A1 of FIG. 3;

FIG. 5 is a perspective view of a gas distribution plate of FIG. 3;

FIG. 6 is an enlarged view of area A2 of FIG. 5;

FIG. 7 is a perspective view of an electrode module including a cooling water inlet channel and a cooling water outlet channel according to an embodiment;

FIG. 8 is a view for explaining a cooling water supply pipe connected to the cooling water inlet channel and the cooling water outlet channel of FIG. 7;

FIG. 9 is a plan view of the cooling water supply pipe of FIG. 8;

FIG. 10 is a view illustrating a matcher and a plasma reactor of the plasma processing device according to an embodiment; and

FIG. 11 is a view for explaining bonding of the object processed by the plasma processing device of FIG. 1 and a chip.

### DETAILED DESCRIPTION

Throughout the present disclosure, identical reference numerals refer to identical components. The present disclosure does not describe all components of embodiments, and generic contents in the technical field to which the present disclosure pertains or redundant contents between the embodiments are omitted. The term “part, module, member, or block” used herein may be implemented by software or hardware, and in some embodiments, a plurality of “parts, modules, members, or blocks” may be implemented with one component, or one “part, module, member, or block” may include a plurality of components.

Throughout the specification, when a portion is “connected” with another portion, this includes not only direct connection but also indirect connection, and the indirect connection includes connection via a wireless communication network.

In addition, when a portion “includes” a component, it means that the portion further includes other components, not excluding the other components unless specifically stated otherwise.

Throughout the specification, when a member is located “on” another member, this includes not only the case in which the member is in contact with the other member but also the case in which another member is between the two members.

The terms such as first, second, and the like are used to distinguish one component from another component, and the components are not limited by the above-mentioned terms.

The terms of a singular form include plural forms unless the context clearly makes an exception.

In steps, identification numerals are used for convenience of description. The identification numerals do not describe the order of the steps, and the steps may be performed differently from the specified order unless the context clearly states a specific order.

Hereinafter, the operating principles and embodiments of the present disclosure will be described with reference to the accompanying drawings.

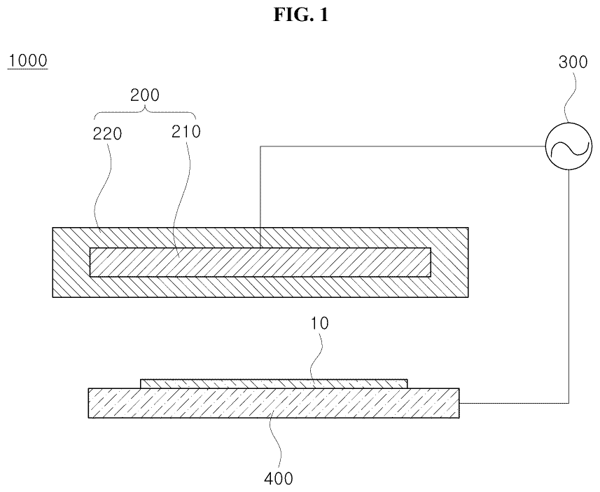

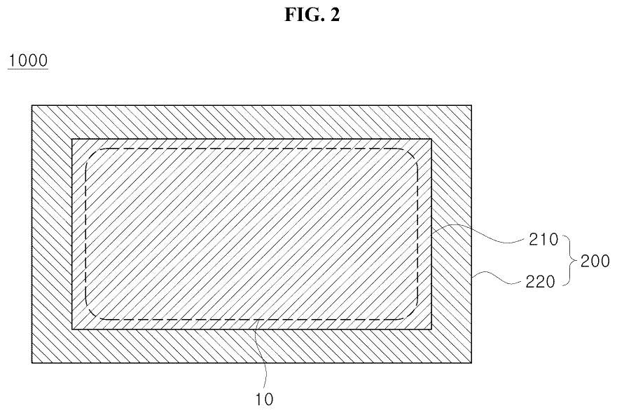

FIG. 1 is a schematic diagram of a plasma processing device 1000 according to an embodiment, and FIG. 2 is a plan view of an electrode 210 and an object 10 to be processed in FIG. 1.

The plasma processing device 1000 according to an embodiment may be a device that performs processing of the object 10, such as removing an oxide film of the object 10 using a physical or chemical reaction such as a plasma phenomenon. According to the plasma processing device 1000 of an embodiment, a processing gas for performing the processing of the object 10 may be injected, the injected processing gas may be excited into plasma by power from a power supply module 300, and the oxide film on the surface of the object 10 may be removed by a substance in a plasma state, such as radicals.

As illustrated in FIG. 1, the plasma processing device 1000 according to an embodiment may include an electrode module 200, a holder 400 (or, a plasma processing plate), and the power supply module 300.

The object 10 to be processed may be disposed on the holder 400. For example, the holder 400 may support the object 10 to be processed. The object 10 to be processed may be, for example, a substrate including a plurality of pads.

The power supply module 300 may provide RF power. When the power is supplied from the power supply module 300 to the electrode 210, plasma discharge may be initiated in a plasma generation space. A first side of the power supply module 300 may be electrically connected to the electrode 210, and a second side of the power supply module 300 may be electrically connected to the holder 400.

The electrode module 200 may be disposed over the holder 400. The electrode module 200 may include the electrode 210 and a dielectric support 220.

The electrode module 200 may be connected to the power supply module 300. For example, the electrode 210 of the electrode module 200 may be electrically connected to the power supply module 300. The electrode 210 may be attached to the dielectric support 220.

The electrode module 200 may have a quadrangular shape when viewed in a plan view. For example, the electrode 210 of the electrode module 200 may have a quadrangular shape when viewed in the plan view. In this case, the electrode module 200 may have a larger area than the object 10 disposed on the holder 400. For example, as illustrated in FIG. 2, the electrode 210 of the electrode module 200 may have a larger area than the object 10 on the holder 400. When viewed in the plan view, the electrode 210 may have a surface shape having a size overlapping the entire area of the object 10. Specifically, the electrode 210 may have the shape of a surface having a larger area than the object 10 such that the periphery of the electrode 210 surrounds the object 10 when viewed in the plan view as illustrated in FIG. 2.

Since the electrode 210 of the electrode module 200 has a quadrangular shape with a surface, the plasma processing device 1000 according to an embodiment may provide plasma in the form of a surface. In this case, the plasma provided in the form of a surface may cover the entire area of the object 10 because the area of the electrode 210 is greater than the area of the object 10. Accordingly, the entire area of the object 10 may be plasma processed by only irradiating plasma once without the movement of the electrode module 200. Thus, according to an embodiment, the efficiency of the plasma processing device 1000 may be improved.

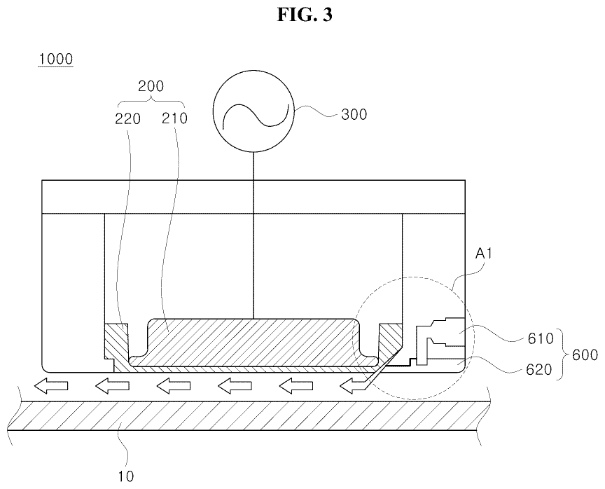

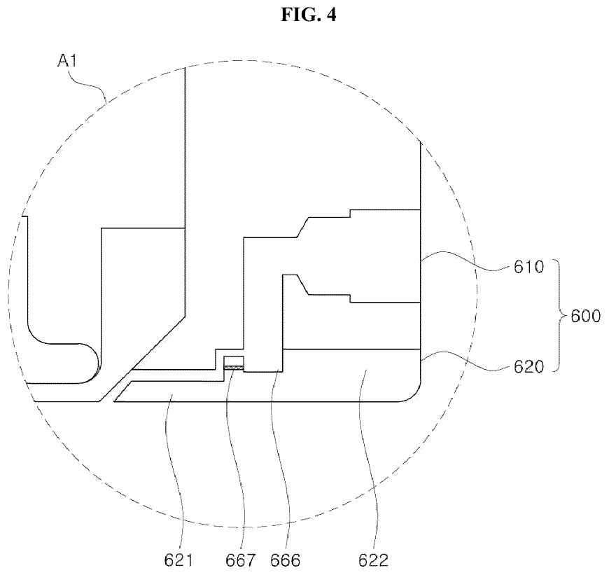

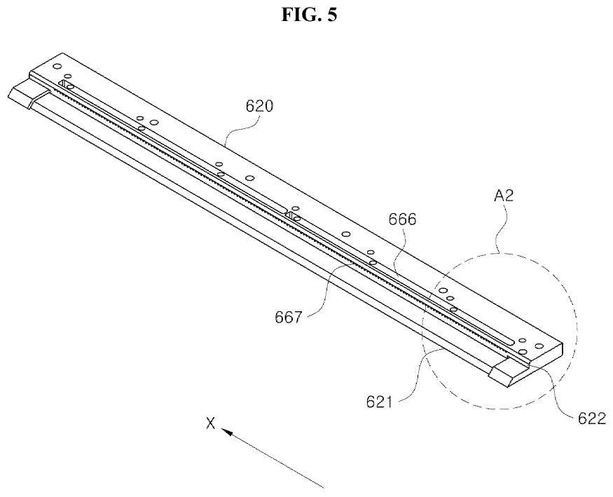

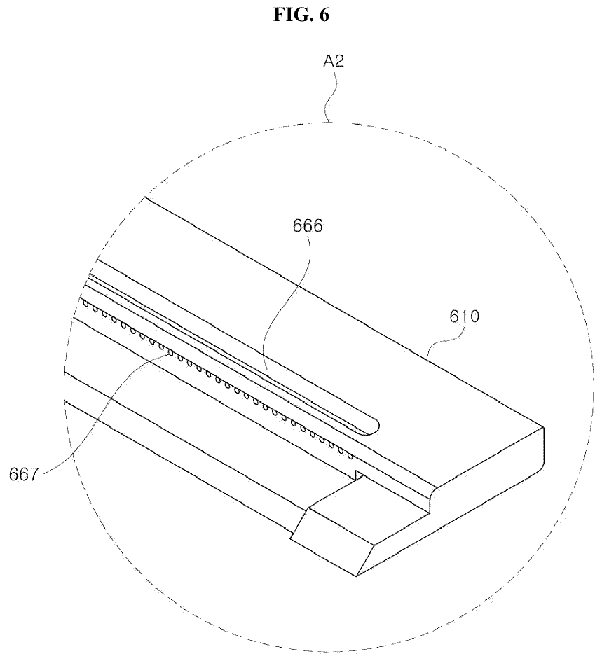

FIG. 3 is a schematic diagram of the plasma processing device 1000 including a gas supply module 600 according to an embodiment. FIG. 4 is an enlarged view of area A1 of FIG. 3. FIG. 5 is a perspective view of a gas distribution plate 620 of FIG. 3. FIG. 6 is an enlarged view of area A2 of FIG. 5.

The plasma processing device 1000 according to an embodiment may further include the gas supply module 600. The gas supply module 600 may supply the above-described processing gas to the object 10 to be processed. The processing gas may include, for example, an electropositive gas, an electronegative gas, or a mixture thereof. For example, the processing gas may include an inert gas, an oxygen-containing gas, a nitrogen-containing gas, a fluorine-containing gas, a carbon-containing gas, or a combination thereof.

The gas supply module 600 may be disposed on a side surface of the electrode module 200. According to an embodiment, the gas supply module 600 may cause the processing gas to flow in one direction. For example, as illustrated in FIG. 3, the gas supply module 600 may provide the processing gas such that the processing gas flows in the direction from the right to the left of the drawing (e.g., in the direction of the arrow in FIG. 3). The gas supply module 600 may include a gas inlet 610 and the gas distribution plate 620.

The gas inlet 610 may supply the processing gas provided from a gas source outside the electrode module 200 to the gas distribution plate 620. The gas inlet 610 may be disposed on a first side of the electrode module 200. For example, the gas inlet 610 may be disposed inside an inner wall of the dielectric support 220 or along a boundary surface of an outer wall of the dielectric support 220.

The gas distribution plate 620 may be disposed on a lower side of the gas inlet 610. The gas distribution plate 620 may be connected to the gas inlet 610. The gas distribution plate 620 may include a lower plate 621 and an upper plate 622.

The upper plate 622 may be disposed on the lower plate 621. The upper plate 622 and the lower plate 621 may be integrally formed with each other. The upper plate 622 may include a plurality of inlet grooves 666 connected to the gas inlet 610 and a plurality of distribution holes 667 (e.g., micro holes) that distribute the processing gas.

The plurality of inlet grooves 666 may be disposed on the upper surface of the upper plate 622. The plurality of inlet grooves 666 may have a shape recessed from the upper surface of the upper plate 622 toward the lower plate 621.

The plurality of distribution holes 667 may be disposed in a side surface of the upper plate 622. For example, the plurality of distribution holes 667 may be disposed along the side surface of the upper plate 622. The plurality of distribution holes 667 may penetrate the side surface of the upper plate 622. In this case, the plurality of distribution holes 667 may penetrate the side surface of the upper plate 622 and may be connected to the inlet grooves 666 of the upper plate 622. A plurality of distribution holes 667 may be connected to one inlet groove 666. FIG. 5 illustrates an example that a plurality of distribution holes 667 are connected to each of two inlet grooves 666.

The processing gas supplied from the gas inlet 610 into the inlet grooves 666 of the upper plate 622 may be distributed to the object 10 through the plurality of distribution holes 667. In this case, as illustrated in FIG. 3, the plurality of distribution holes 667 may distribute the processing gas such that the processing gas flows in the direction from the right to the left of the drawing (e.g., in the direction of the arrow in FIG. 3).

The plurality of distribution holes 667 may be more densely disposed in the direction from the gas inlet 610 to the holder 400. For example, the density of the distribution holes 667 may be changed depending on the direction of inflow of the gas. Specifically, the density ρ(x) of the distribution holes 667 may be defined by Equation 1 below depending on the distance x from the gas inlet 610.

$$ρ ( x ) = ρ\_ 0 + k x \qquad 〈 Equation 1 〉$$

In Equation 1 above, ρ_0 represents the density of the initial distribution holes 667 at the gas inlet 610, and k represents the rate of increase in the density of the distribution holes 667. According to Equation 1, the density of the distribution holes 667 may increase in the direction of inflow of the gas. For example, when the gas inlet 610 is connected to the inlet groove 666 of the gas distribution plate 620 in area A2 (e.g., at an edge of the gas distribution plate 620) as illustrated in FIG. 5, the density of the distribution holes 667 may increase in the x direction. In other words, the density of the distribution holes 667 may gradually increase as the distance from the gas inlet 610 increases. Accordingly, a gas distribution effect may be maximized, and plasma uniformity may be improved.

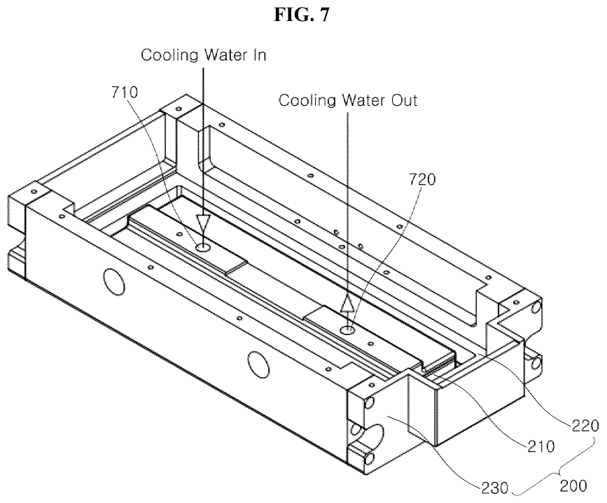

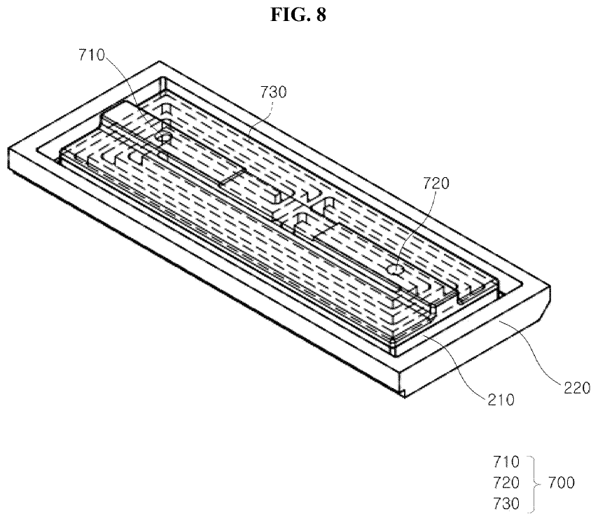

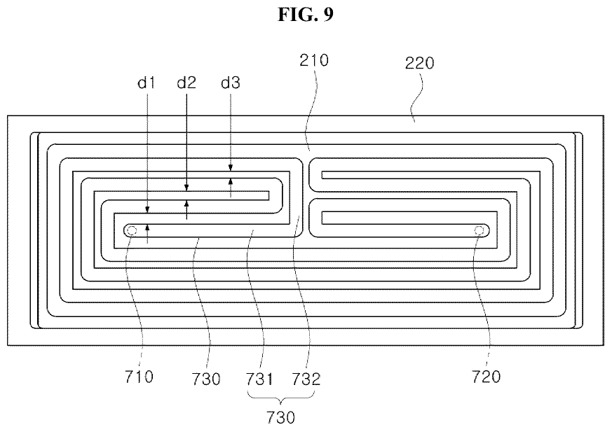

FIG. 7 is a perspective view of the electrode module 200 including a cooling water inlet channel 710 and a cooling water outlet channel 720 according to an embodiment. FIG. 8 is a view for explaining a cooling water supply pipe 730 connected to the cooling water inlet channel 710 and the cooling water outlet channel 720 of FIG. 7. FIG. 9 is a plan view of the cooling water supply pipe 730 of FIG. 8.

As illustrated in FIG. 7, the electrode module 200 of the plasma processing device 1000 according to an embodiment may include the electrode 210, the dielectric support 220, and an outer frame 230. The outer frame 230 may be disposed outside the dielectric support 220 to surround the dielectric support 220. The dielectric support 220 may be attached to the outer frame 230.

In addition, as illustrated in FIGS. 7 to 9, the electrode module 200 of the plasma processing device 1000 according to an embodiment may further include a cooling module 700. The cooling module 700 may prevent overheating of the electrode module 200. For example, the cooling module 700 may prevent overheating of the electrode 210 by releasing heat of the electrode 210 to the outside using cooling water.

As illustrated in FIG. 8, the cooling module 700 may include the cooling water inlet channel 710, the cooling water outlet channel 720, and the cooling water supply pipe 730.

The cooling water inlet channel 710 may receive the cooling water from the outside and may supply the cooling water to the cooling water supply pipe 730. To achieve this, the cooling water inlet channel 710 may be connected to a first side of the cooling water supply pipe 730. For example, the cooling water inlet channel 710 may be connected to a first end of the cooling water supply pipe 730.

The cooling water outlet channel 720 may discharge the cooling water from the cooling water supply pipe 730 to the outside. To achieve this, the cooling water outlet channel 720 may be connected to a second side of the cooling water supply pipe 730. For example, the cooling water outlet channel 720 may be connected to a second end of the cooling water supply pipe 730.

As illustrated in FIGS. 8 and 9, the cooling water supply pipe 730 may be disposed on the electrode 210. The first side of the cooling water supply pipe 730 may be connected to the cooling water inlet channel 710, and the second side of the water cooling supply pipe 730 may be connected to the cooling water outlet channel 720. As illustrated in FIG. 9, the cooling water supply pipe 730 may have a bent shape. For example, as illustrated in FIG. 9, when viewed in a plan view, the cooling water supply pipe 730 may be disposed on the electrode 210 while surrounding the cooling water inlet channel 710 and the cooling water outlet channel 720 in a spiral shape. In other words, the cooling water supply pipe 730 may include a plurality of sub-supply pipes 731 and 732 extending in different directions, and the plurality of sub-supply pipes 731 and 732 may be disposed in a spiral shape and may be connected with each other. Here, the plurality of sub-supply pipes may include the first sub-supply pipes 731 extending in a first direction (e.g., a horizontal direction) and the second sub-supply pipes 732 extending in a second direction (e.g., a vertical direction crossing the first direction).

The cooling water introduced into the cooling water supply pipe 730 through the cooling water inlet channel 710 may move from the periphery of the electrode 210 toward the center of the electrode 210 along the cooling water supply pipe 730 and thereafter may be discharged to the outside through the cooling water outlet channel 720.

The gap between the sub-supply pipes of the cooling water supply pipe 730 that face each other may vary depending on the distance from the cooling water inlet channel 710. For example, the adjacent first sub-supply pipes 731 may be disposed with a smaller gap therebetween as the distance from the cooling water inlet channel 710 increases. For example, as illustrated in FIG. 9, when the gap between the first sub-supply pipes 731 closest to the cooling water inlet channel 710 is defined as a first gap d1, the gap between the first sub-supply pipes 731 next closest to the cooling water inlet channel 710 is defined as a second gap d2, and the gap between the first sub-supply pipes 731 furthest from the cooling water inlet channel 710 is defined as a third gap d3, the second gap d2 may be smaller than the first gap d1 and greater than the third gap d3.

According to an embodiment, the gap d(r) between the sub-supply pipes depending on the distance from the cooling water inlet channel 710 to the sub-supply pipes of the cooling water supply pipe 730 may be defined by Equation 2 below.

$$d ( r ) = d\_ 0 - cr \qquad 〈 Equation 2 〉$$

In Equation 2 above, r represents the distance between the cooling water inlet channel 710 and the sub-supply pipe (e.g., the first sub-supply pipe 731) of the cooling water supply pipe 730, d_0 represents the initial gap between the sub-supply pipes (e.g., the first sub-supply pipes 731) facing each other at the cooling water inlet channel 710, and c represents a gap reduction rate. Accordingly, the gap between the sub-supply pipes of the cooling water supply pipe 730 may be narrowed toward the periphery of the electrode 210 so that heat dissipation efficiency may be improved and overheating of the electrode 210 may be prevented.

According to an embodiment, the shape of the electrode 210 for further improving plasma uniformity may be optimized. For example, the shape of the edge of the electrode 210 may be changed, and a specific pattern may be added to the surface of the electrode 210.

According to an embodiment, the efficiency of removing the oxide film of the object 10 may be maximized by optimizing various plasma generation conditions such as a plasma generation frequency, power, a gas type, and a gas flow rate. For example, the oxide film removal efficiency E may be optimized by adjusting various variables, such as the plasma generation frequency (F), the power (P), the gas type (G), and the gas flow rate (Q), as in Equation 3 below to optimize the plasma generation conditions. For example, the oxide film removal efficiency E may be defined as a function of the plasma generation frequency (F), the power (P), the gas type (G), and the gas flow rate (Q).

$$E = f ( F , P , G , Q ) \qquad 〈 Equation 3 〉$$

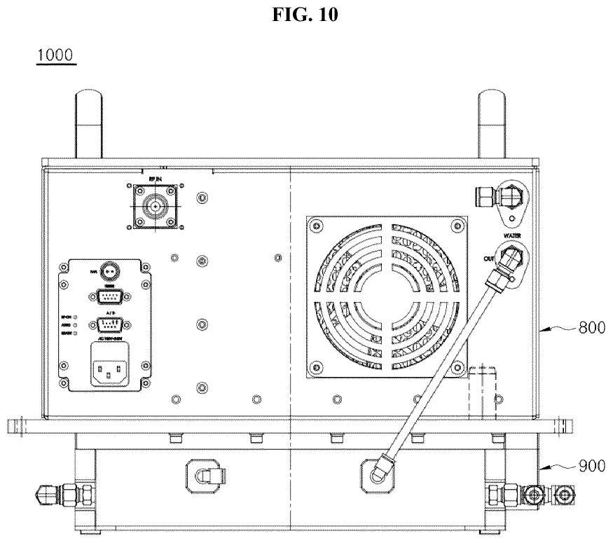

FIG. 10 is a view illustrating a matcher and a plasma reactor of the plasma processing device 1000 according to an embodiment.

As illustrated in FIG. 10, the above-described power supply module 300 may further include the matcher 800 (or, a matching network), and the matcher 800 and the plasma reactor 900 of the plasma processing device 1000 may be implemented as one body. For example, the matcher 800 and the plasma reactor 900 may be integrated with each other to constitute one module. Accordingly, power loss may be minimized, and impedance matching stability may be improved.

An oxide film removal method of the above-configured plasma processing device according to an embodiment will be described as follows.

First, the object 10 to be processed may be disposed on the holder 400. Here, the object 10 to be processed may be a substrate including a plurality of pads. In this case, the object 10 to be processed may be disposed on the holder 400 such that the pads face toward the electrode module 200.

Next, power from the power supply module 300 may be supplied to the electrode 210 of the electrode module 200 to generate plasma.

Then, the processing gas may be supplied to the holder 400 through the gas supply module 600. Accordingly, the oxide film of the object 10 may be removed. Here, the oxide film may include oxide films formed on surfaces of the pads.

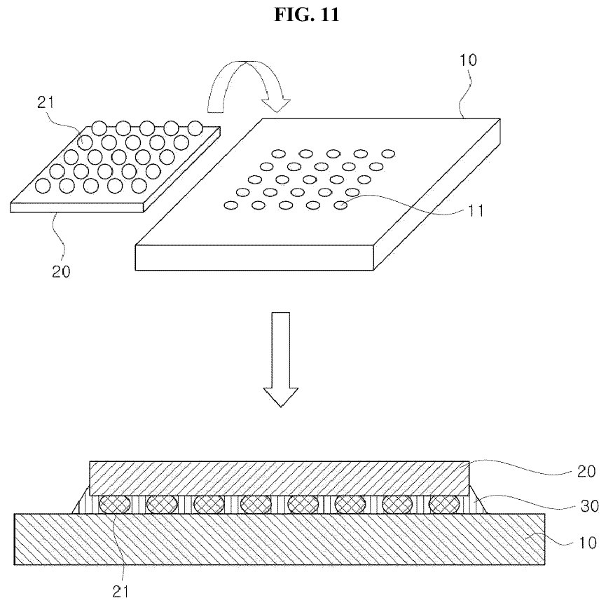

FIG. 11 is a view for explaining bonding of the object 10 processed by the plasma processing device 1000 of FIG. 1 and a chip (e.g., a semiconductor chip).

As illustrated in FIG. 11, the object 10 may include a plurality of pads 11, and the chip 20 may include a plurality of bumps 21 (e.g., solder bumps).

Oxide films formed on the pads 11 of the object 10 may be removed by the plasma processing device 1000 of FIG. 1. The object 10 processed in this manner and the chip 20 may be bonded to each other. For example, after the processed object 10 is turned upside down, the pads 11 of the object 10 (e.g., a flip substrate) and the bumps 21 of the chip 20 may be electrically connected with each other. Thereafter, an insulating resin may fill the space between the object 10 and the chip 20 through an underfill process.

Since the pads 11 of the object 10 from which the oxide films are removed and the bumps 21 of the chip 20 are bonded to each other, the electrical connection between the object 10 and the chip 20 may be improved.

Meanwhile, the plasma processing device 1000 according to an embodiment may also remove oxide films formed on the bumps 21 of the chip 20 in FIG. 11 as the above-described object to be processed.

According to the present disclosure, the oxide films and the organic contaminants formed on the bumps or the pads may be effectively removed even without the use of flux. In particular, according to an embodiment, when viewed in a plan view, the electrode may have a surface shape having a size overlapping the entire area of the object to be processed. Accordingly, plasma provided in the form of a plane may cover the entire area of the object. Thus, the entire area of the object may be plasma processed by only irradiating the plasma once without the movement of the electrode module so that the efficiency of the plasma processing device may be improved. For example, productivity may be significantly improved by minimizing repetitive processes and reducing processing time through large-area processing.

Re-oxidation and contamination may be minimized so that the oxide film may be uniformly and stably removed. Thus, product quality may be improved.

A reduction in facility investment costs and an improvement in the use of space may be achieved through simplification and compactness of the device.

An environmentally-friendly process is possible because flux, which is a hazardous chemical, is not used.

An in-line configuration suitable for a continuous process is possible, and thus production efficiency may be maximized.

Accurate and stable process control may be performed through uniform plasma processing.

Power loss may be minimized, impedance matching stability may be improved, and overheating of the electrode may be prevented.

Effects of the present disclosure are not limited to the aforementioned effects, and any other effects not mentioned herein will be clearly understood from the following description by those skilled in the art to which the present disclosure pertains.

While the present disclosure has been described with reference to embodiments, it will be apparent to those skilled in the art that various changes and modifications may be made without departing from the spirit and scope of the present disclosure. Therefore, it should be understood that the above embodiments are not limiting, but illustrative.

What is claimed is:

1. A plasma processing device comprising:
a holder configured to support an object to be processed;
an electrode module disposed over the holder, the electrode module including an electrode; and
a power supply module configured to supply power to the electrode of the electrode module,
wherein when viewed in a plan view, the electrode has a surface shape having a size overlapping the entire area of the object disposed on the holder.

2. The plasma processing device of claim 1, wherein when viewed in the plan view, a periphery of the electrode surrounds the object disposed on the holder.

3. The plasma processing device of claim 1, further comprising:
a gas supply module disposed on a first side of the electrode module and configured to supply a processing gas.

4. The plasma processing device of claim 3, wherein the gas supply module includes:
a gas inlet disposed in a side surface of the electrode module; and
a plurality of distribution holes configured to supply the processing gas from the gas inlet in one direction.

5. The plasma processing device of claim 4, wherein the plurality of distribution holes are more densely disposed as a distance from the gas inlet increases.

6. The plasma processing device of claim 1, further comprising:
a cooling module disposed on the electrode of the electrode module.

7. The plasma processing device of claim 6, wherein the cooling module includes:
a cooling water supply pipe;
a cooling water inlet channel connected to a first side of the cooling water supply pipe; and
a cooling water outlet channel connected to a second side of the cooling water supply pipe.

8. The plasma processing device of claim 7, wherein the cooling water supply pipe includes a plurality of first sub-supply pipes and a plurality of second sub-supply pipes configured to extend in different directions and connected with each other, and
wherein the first sub-supply pipes adjacent to each other are disposed with a smaller gap therebetween as a distance from the cooling water inlet channel increases.

9. The plasma processing device of claim 1, wherein the power supply module includes a matcher, and
wherein the matcher is integrated with a plasma reactor.

10. A method for removing an oxide film using the plasma processing device of claim 3, the method comprising:
a step of placing the object to be processed on the holder;
a step of generating plasma by supplying the power to the electrode through the power supply module; and
a step of removing an oxide film of the object by supplying the processing gas to the holder through the gas supply module.
